(19) United States
(12) Patent Application Publication
(10) Pub. No.: US 2025/0164894 A1
(43) Pub. Date: May 22, 2025

(54) METHOD OF CORRECTING REGISTRATION ERRORS, METHOD OF MANUFACTURING MASK, AND METHOD OF MANUFACTURING INTEGRATED CIRCUIT

(71) Applicant: SAMSUNG ELECTRONICS CO., LTD., SUWON-SI (KR)

(72) Inventors: Sunghoon Park, Suwon-si (KR); Junesik Hwang, Suwon-si (KR)

(21) Appl. No.: 18/952,436

(22) Filed: Nov. 19, 2024

(30) Foreign Application Priority Data
Nov. 20, 2023 (KR) 10-2023-0161434

(51) Int. Cl. G03F 7/00

(52) U.S. Cl. CPC G03F 7/70516; G03F 7/70558; G03F 7/70625

(57) ABSTRACT

A method of correcting a registration error of a mask includes: performing a test exposure using an exposure apparatus; extracting registration error data according to a dose difference of beams in a preset process condition, through the test exposure; providing a dose map for a pattern area of the mask; and generating a correction map using the dose map and the registration error data.

### CROSS-REFERENCE TO RELATED APPLICATION

This application is based on and claims priority under 35 U.S.C. § 119 to Korean Patent Application No. 10-2023-0161434, filed on Nov. 20, 2023, in the Korean Intellectual Property Office, the disclosure of which is incorporated by reference herein in its entirety.

### BACKGROUND

### 1. Technical Field

The inventive concept relates to a method of correcting registration errors of a mask manufactured using an exposure apparatus, a method of manufacturing a mask, and a method of manufacturing an integrated circuit.

### 2. Discussion of Related Art

Photomasks may be used with lithographic techniques to generate features of semiconductor devices. As the design rules of the semiconductor devices become smaller, pattern accuracy of the photomasks may also need to be increased. For this reason, registration errors representing the positional accuracy of patterns on photomasks are a quality factor directly related to the overlay quality of wafers.

### SUMMARY

It is an object of the inventive concept to provide a method of correcting a registration error of a mask manufactured using an exposure apparatus, a method of manufacturing a mask, and a method of manufacturing an integrated circuit, capable of reducing registration errors to prevent wafer overlay errors.

Also, objects of the inventive concept are not limited to the above-mentioned objects, and other objects will be clearly understood by one of ordinary skill in the art from the following descriptions.

The inventive concept may provide a method of correcting a registration error of a mask manufactured using an exposure apparatus, including performing a test exposure using an exposure apparatus, extracting registration error data according to a dose difference of beams in a preset process condition, through the test exposure, providing a dose map for a pattern area of the mask, and generating a correction map using the dose map and the registration error data.

The inventive concept may provide a method of manufacturing a mask, including performing a test exposure, extracting registration error data according to a dose difference of beams in a preset process condition, through the test exposure, providing a dose map for a pattern area of the mask divided into preset unit areas, generating a correction map using the dose map and the registration error data, and exposing the mask by using the correction map.

The inventive concept may provide a method of manufacturing an integrated circuit, including providing a wafer including a feature layer, forming a photoresist layer on the feature layer, preparing a mask for which a registration error has been corrected, exposing the photoresist layer using the mask, developing the photoresist layer to form a photoresist pattern, and processing the feature layer using the photoresist pattern, wherein the preparing of the mask for which the registration error has been corrected may include performing a test exposure using an E-beam exposure apparatus, extracting registration error data according to a dose difference of E-beams in a preset process condition, through the test exposure of, providing a dose map for a pattern area of the mask divided into preset unit areas, generating a correction map using the registration error data and the dose map, and exposing the mask using the correction map correcting a registration error of the E-beam exposure apparatus.

### BRIEF DESCRIPTION OF THE DRAWINGS

Embodiments will be more clearly understood from the following detailed description taken in conjunction with the accompanying drawings in which:

FIG. 1 is a conceptual view of an exposure mechanism of an E-beam exposure apparatus used in a mask manufacturing method according to an embodiment;

FIG. 2 is a view illustrating an operation of an E-beam exposure apparatus used in a mask manufacturing method according to an embodiment;

FIG. 3 is a conceptual view of a control circuit of an E-beam exposure apparatus used in a registration error correcting method according to an embodiment;

FIG. 4 is a flowchart illustrating a registration error correcting method and a mask manufacturing method according to an embodiment;

FIG. 5A shows a target registration map of a mask pattern, and FIG. 5B shows a real registration map of a mask pattern;

FIG. 6 is an experimental data graph obtained by measuring registration errors according to doses;

FIG. 7 is a conceptual view for describing a correction map according to an embodiment;

FIG. 8 is a two-dimensional map showing measured results of registration errors of a mask corrected by a registration error correction method according to an embodiment;

FIG. 9 is an exemplary cross-sectional view of a mask formed by a mask manufacturing method according to an embodiment; and

FIG. 10 is a flowchart illustrating an integrated circuit manufacturing method according to an embodiment.

### DETAILED DESCRIPTION

Hereinafter, embodiments will be described in detail with reference to the accompanying drawings. In the drawings, like components are assigned like reference numerals, and repetitive descriptions thereof may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

Extreme ultraviolet (EUV) light may be used for performing an optical lithography process in manufacturing a semiconductor device. The optical lithography process using EUV light may have smaller features and improved resolutions as compared to conventional optical lithography processes. EUV light in the context of optical lithography may have a wavelength between about 4 and 40 nanometers, and more particularly about 13.5 nanometers.

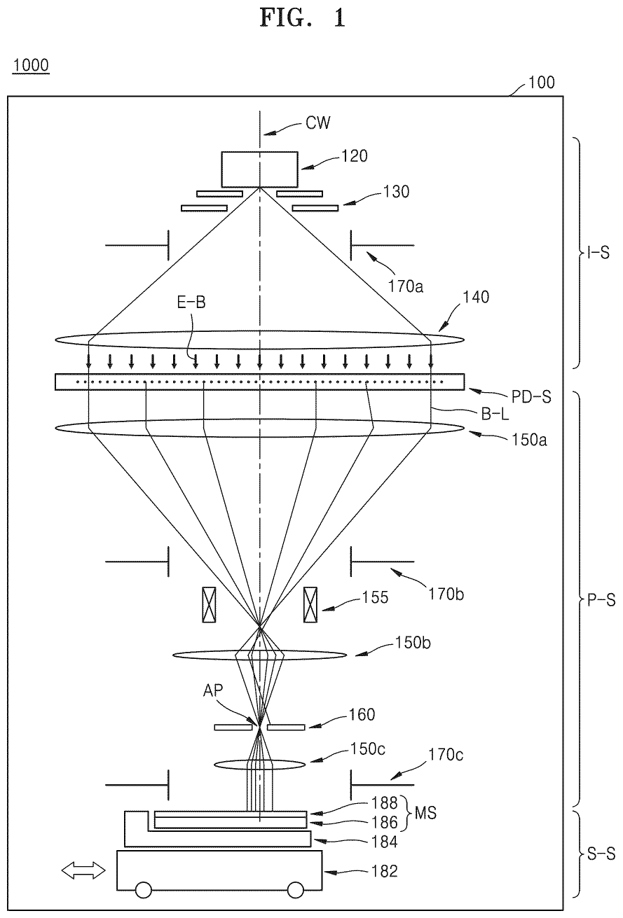

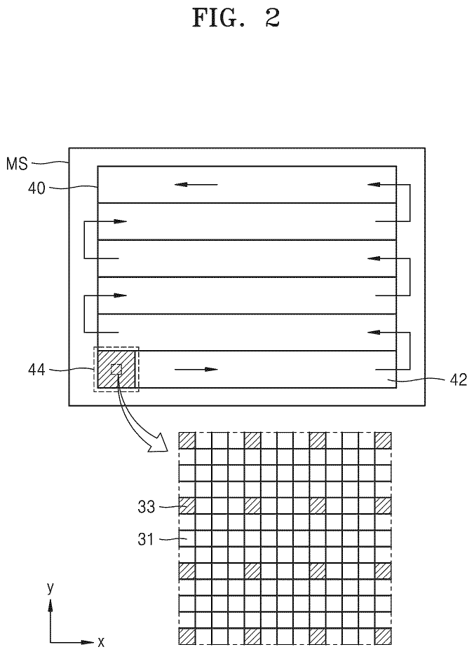

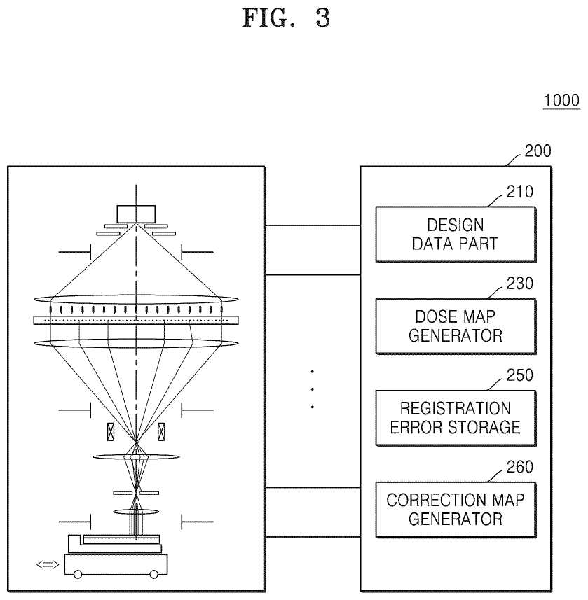

The EUV light may be created using an E-beam exposure apparatus. FIG. 1 is a conceptual view of an exposure mechanism of an E-beam exposure apparatus, which may be used in a mask manufacturing method according to an embodiment. FIG. 2 is a view illustrating an operation of an E-beam exposure apparatus, which may be used in a mask manufacturing method according to an embodiment. FIG. 3 is a conceptual view of a control circuit of an E-beam exposure apparatus according to an embodiment.

As shown in FIG. 1, an exposure mechanism 100 of an E-beam exposure apparatus 1000 may include an illumination system I-S, a pattern definition system PD-S, a projection system P-S, and a stage system S-S. The illumination system I-S, pattern definition system PD-S, projection system P-S, and stage system S-S may be arranged from top to bottom in a vertical direction. Components of the exposure mechanism 100 may be installed in a vacuum housing 110 that may be maintained at a high vacuum.

The illumination system I-S may include an electron gun 120, an extraction device 130, and a condensing lens 140. The electron gun 120 may be, for example, a short key-type electron gun or a thermal field emission-type electron gun. The electron gun 120 is not limited to these, and different types of the electron gun 120 may be implemented. While an accelerating voltage is applied to the electron gun 120, electrons may be emitted by the electron gun 120. The extraction device 130 may accelerate particles, for example, electrons with preset energy of, typically, several keV, for example, about 5 keV. The condensing lens 140 may convert the electrons emitted from the electron gun 120 into a wide and substantially telecentric E-beam E-B, and the E-beam E-B may be used as a beam for lithography.

The E-beam E-B may enter the pattern definition system PD-S. The pattern definition system PD-S may have a shape of a plate including a plurality of apertures. Accordingly, the pattern definition system PD-S may also be referred to as a Plate Aperture System (APS). The apertures may be disposed in the plate with a structure of a two-dimensional array of, for example, 512*512 (=262,144). The number and structure of the apertures in the pattern definition system PD-S are not limited to examples described herein.

The pattern definition system PD-S may divide the E-beam E-B that has entered the pattern definition system PD-S into a plurality of beamlets B-L by using the apertures. Also, beamlets B-L that have passed through at least some of the apertures may arrive at a target, for example, a mask MS, and beamlets B-L that have passed through remaining apertures may fail to arrive at the target. Accordingly, the beamlets B-L that have exited the pattern definition system PD-S may be divided into on-beams that arrived at the target and off-beams that fail to arrive at the target. For example, the on-beams may arrive at the target, that is, the mask MS, through an aperture AP of an aperture plate 160, and the off-beams may be blocked by the aperture plate 160.

The pattern definition system PD-S may structure incident E-beams E-B into patterned beams. In addition, the pattern definition system PD-S may include a deflection element provided in a plate to divide beamlets B-L into on-beams and off-beams. In this way, the pattern definition system PD-S may adjust tilts of beamlets B-L through the deflection element, and may divide the beamlets B-L into on-beams and off-beams. The deflection element may adjust the tilts of the beamlets B-L through a voltage.

Beamlets B-L that have exited the pattern definition system PD-S may enter the projection system P-S. The projection system P-S may reduce the beamlets B-L such that some of the beamlets B-L may enter the target, that is, the mask MS, by passing through the aperture AP of the aperture plate 160, and the remaining beamlets B-L may enter an upper surface of the aperture plate 160.

The projection system P-S may include a plurality of electromagnetic-optical projector elements 150a, 150b, and 150c. The electromagnetic-optical projector elements 150a, 150b, and 150c may include, for example, an electrostatic and/or magnetic lens and a plurality of deflection elements. Also, the exposure mechanism 100 may include a plurality of deflection elements 170a, 170b, and 170c for deflecting an E-beam E-B in a side direction with respect to an optical axis CW in the illumination system I-S and the projection system P-S. In addition, the projection system P-S may include a solenoid 155, and the solenoid 155 may provide an axial magnetic field.

The beamlets B-L may be reduced while forming a plurality of intersections, for example, two intersections through the electromagnetic-optical projector elements 150a, 150b, and 150c, in the projection system P-S. The beamlets B-L may pass through the aperture AP of the aperture plate 160 while forming an intersection at the aperture AP and may enter the target, that is, the mask MS.

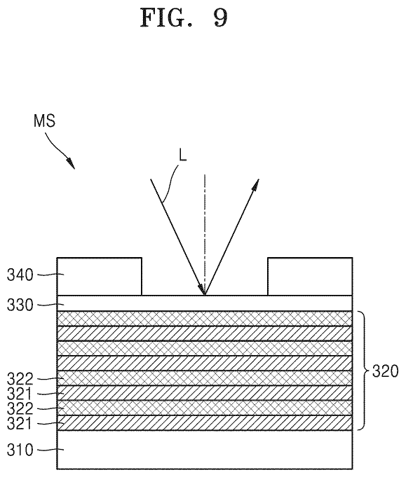

The stage system S-S may include a substrate stage 182, a chuck 184, and the mask MS. The mask MS may include a substrate 186 and an E-beam resist layer 188 disposed on the substrate 186. The substrate 186 of the mask MS may be, for example, a blank mask. The blank mask may be a mask in which no pattern has been formed. The mask MS may be fixed to the chuck 184, and may move with the substrate stage 182. For example, the mask MS may be fixed to the chuck 184, and may move two-dimensionally together with the substrate stage 182. The mask MS is described in detail in the descriptions of a mask manufacturing method illustrated in FIG. 9.

The exposure mechanism 100 may perform exposure by receiving information about a pattern that is a target to be exposed from a control circuit 200 (see FIG. 3). The information about a pattern may include a pattern shape, and a dose for each pattern area. The information about a pattern may include additional information. In addition, a series of processes may be performed before an E-beam exposure process to form a pattern on a mask. The series of processes that are performed before the E-beam exposure process may include designing a layout of a target pattern, obtaining design data subjected to Optical Proximity Correction (OPC), and transferring the design data as Mask Tape-Out (MTO) data to a mask manufacturing team. Thereafter, Mask Data Preparation (MDP) including fracturing, augmentation, and verification may be performed. The MDP may include other processes. Also, in the MDP, a process of converting mask data into pixel data may be performed. The pixel data may be data that is actually used for a real exposure and may include data about a shape as a target to be exposed and data about a dose assigned to each shape. Herein, the data about a shape may be bit-map data resulting from transforming shape data into vector data through registration, etc. The information about a pattern may include shape data and dose data. The information about the dose may include data about, for example, areal dosage or fluence. For example, the dose may describe how many ions impact a given area. For example, the dose may be increased by one or more of increasing an amount of ions generated or by decreasing an area of a beam. The dose may also have a time component. Upon manufacturing of a mask by performing exposure according to the design data described herein, a registration error (a positional error of a mask pattern with respect to the design data) may occur in a mask pattern.

Referring to FIG. 2, a pattern area 40 of the mask MS may be divided into a plurality of stripe areas 42. According to an embodiment, the plurality of stripe areas 42 may each have a shape of a rectangle having a preset width, and the plurality of stripe areas 42 may be arranged, for example, in a y direction.

According to an embodiment, the substrate stage 182 (see FIG. 1) may be moved to a position at the left end of a first stripe area 42 corresponding to an irradiation area 44, which may be irradiated with a multi-beam shot, and writing may start. While writing is performed on the first stripe area 42, the substrate stage 182 may move counter to the x direction to perform irradiation in the x direction. According to an embodiment, the substrate stage 182 may move at a constant velocity. After writing on the first stripe area 42 is completed, the substrate stage 182 may move counter to the y direction to a position at the right end of a second stripe area 42 corresponding to the irradiation area 44, and the substrate stage 182 may move in the x direction to perform writing counter to the x direction. In this way, writing may be performed on the plurality of stripe areas 42 while changing directions alternately. FIG. 2 shows a case in which writing is performed once on each stripe area 42, although a method is not limited thereto. Further, multiple writing processes may be performed on a same area.

A shot of the E-beam exposure apparatus 1000 may form a plurality of shot patterns at once by a multi-beam formed by the plurality of apertures of the pattern definition system PD-S (see FIG. 1). In this case, the number of shot patterns may be equal to the number of apertures formed in the pattern definition system PD-S.

Referring to FIG. 2, a plurality of control grids 31 arranged in a lattice form. A pitch of the control grids may have a size of a beam of a multi-beam, which may be defined in the pattern area 40 (or the stripe areas 42) of the mask MS. According to an embodiment, the pitch of the plurality of control grids 31 may be in a range of several nm, tens of nm, or hundreds of nm. The plurality of control grids 31 may be irradiation locations on a design of a multi-beam. The pitch of the plurality of control grids 31 is not limited to the size of a beam and may have an arbitrary controllable size. A plurality of pixels 33 virtually segmented in a mesh form with a size matching the pitch of the plurality of control grids 31 may be defined. Each of the plurality of pixels 33 may be an irradiation unit area for each beam of a multi-beam.

Referring to FIG. 3, the E-beam exposure apparatus 1000 may include the control circuit 200. The control circuit 200 may be electrically connected to the exposure mechanism 100 described with reference to FIG. 1. The control circuit 200 may transmit/receive information for an operation of the E-beam exposure apparatus 1000 to/from the exposure mechanism 100.

According to an embodiment, the control circuit 200 may include a design data part 210, a dose map generator 230, a registration error storage 250, and a correction map generator 260.

The design data part 210 may be a memory such as a magnetic disc. The design data part 210 may receive design data of a mask pattern and store the design data of the mask pattern. The design data may be received from outside of the E-beam exposure apparatus 1000. The design data may include a plurality of pieces of figure pattern information about the mask pattern and include information of a figure code, coordinates, and size for each figure pattern. The design data may include additional data.

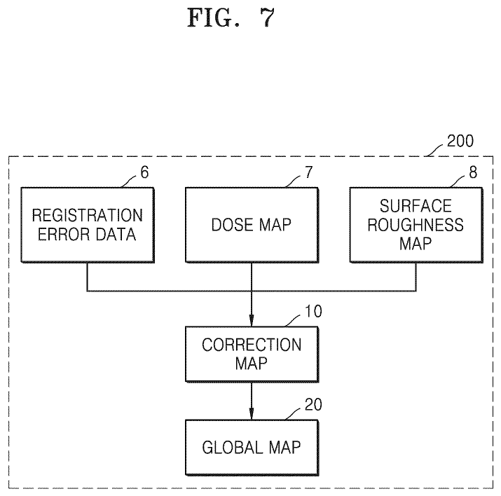

The dose map generator 230 may generate a dose map 7 (see FIG. 7). The dose map generator 230 may generate a dose map in which an incident irradiation amount for each pixel 33 (see FIG. 2) may be defined. The incident irradiation amount for each pixel 33 may be an incident irradiation amount that is expected to be irradiated to a control grid of the corresponding pixel 33, according to a design.

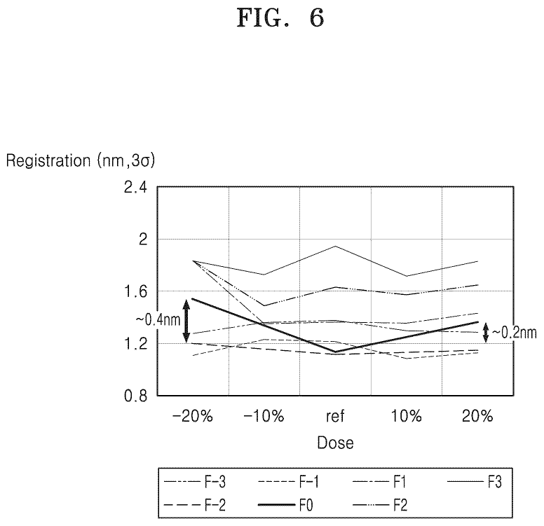

The registration error storage 250 may be a memory such as a magnetic disc. In the E-beam exposure apparatus 1000, distortion may occur in an exposure field due to characteristics of an optical system, and the distortion may cause registration errors. In addition, different registration errors may occur according to doses under the same process conditions. Registration errors may be measured through a test of exposing a mask. The test may extract registration error data 6 (see FIG. 6 and FIG. 7) by measuring, with a position detector, a position of a resist pattern generated by irradiating a multi-beam onto an evaluation substrate on which a resist is applied, and developing the evaluation substrate. The registration error data 6 may be stored in the registration error storage 250.

The correction map generator 260 may generate a correction map 10 (see FIG. 7) by calculating, for each pixel 33, a correction value for correcting a registration error of a mask pattern, which may be caused by position deviation of a beam irradiated to the corresponding pixel 33 according to a writing sequence. The registration error may be, for example, a positional error of a mask pattern. The registration error may be caused by other factors.

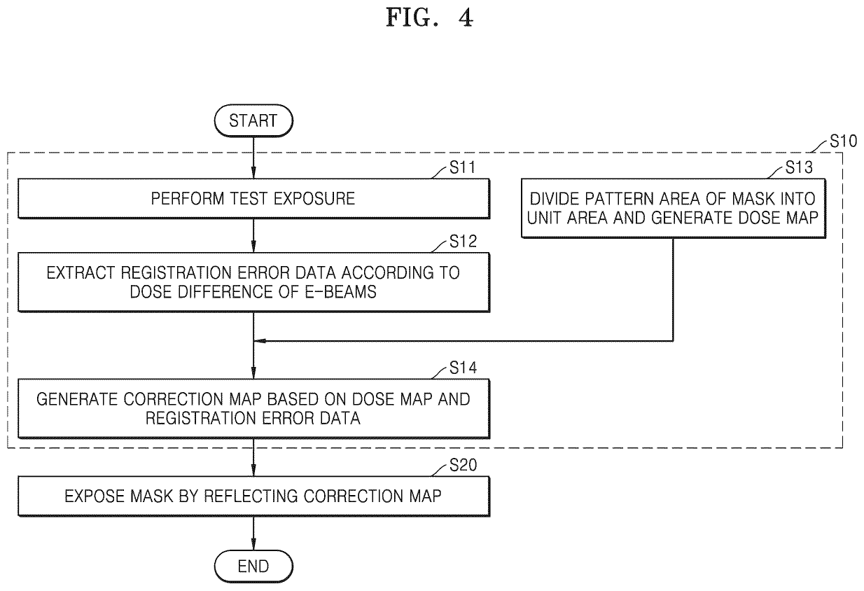

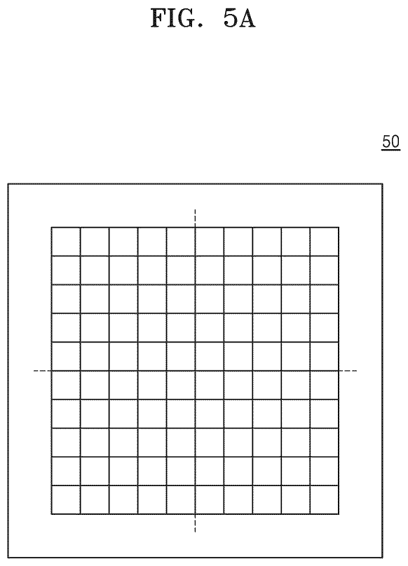

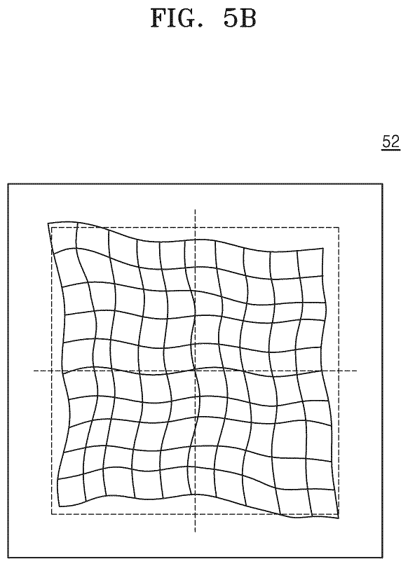

FIG. 4 is a flowchart illustrating a registration error correcting method and a mask manufacturing method according to an embodiment. FIG. 5A shows a target registration map of a mask pattern. FIG. 5B shows a real registration map of a mask pattern. FIG. 6 is an experimental data graph obtained by measuring registration errors according to doses in different focus conditions through a test.

Referring to FIG. 5A, in a case in which a registration error is 0 (zero), a target registration map 50 of a mask pattern may appear. In this case, the mask pattern may have the same shape at a same position as a mask pattern of design data. In practice, it may be unlikely that a target mask with a registration error of zero, as shown in FIG. 5A, is manufactured. A registration error may be caused, for example, in manufacturing equipment (for example, the E-beam exposure apparatus 1000 of FIG. 1), or by an exposure process condition (for example, dose). That is, a registration error may be caused according to a process condition, and/or hardware. FIG. 5B shows an example of a real registration map 52 that appears due to mask patterns having irregular registration errors.

Referring to FIG. 4, a method of correcting a registration error of a mask according to an embodiment may include operation S11 of performing a test exposure, operation S12 of extracting registration error data according to a dose difference of E-beams, operation S13 of dividing a pattern area of the mask into a preset unit area and generating a dose map, and operation S14 of generating a correction map based on the dose map and the registration error data. The operations of FIG. 4 may be performed in different orders. For example, an operation S13 of generating the dose map may be performed independently of operation S11 of performing the test and independently of operation S12 of extracting the registration error data.

Operation S11 of performing the test exposure may be performed by the E-beam exposure apparatus 1000 of FIG. 1. The test may be performed to measure a registration error of the E-beam exposure apparatus according to a preset process condition. The preset process condition may include a focus condition and a dose condition of an exposure using the E-beam exposure apparatus 1000 (see FIG. 1).

Operation S12 of extracting the registration error data according to the dose difference may be performed while the test is being performed. Registration error data according to doses may include a plurality of error values. For example, the registration error data according to doses may include a first error value associated with a first dose and a second error value associated with a second dose. The first dose and the second dose may cause the first error value and the second error value, respectively. The first dose and the second dose may have different values. According to an embodiment, the first error value and the second error value may be obtained in the same focus condition. According to an embodiment, the second dose may be in a range of about 120% to about 200% of the first dose. According to an embodiment, the first dose may be a value selected to reduce or minimize a change of a Critical Dimension (CD) of a pattern according to a focus change of an E-beam, and the second dose may have a value that is greater or less than the first dose. The registration error data according to doses may be used together with the dose map in operation S14 of generating the correction map.

The x axis in the graph shown in FIG. 6 may correspond to a dose. A dose of a reference (ref) value may be set to 100%, and differences between the dose of the ref value and doses of other values may be expressed as percentages. For example, a dose of 20% may be a dose having a value of 120% compared to the dose of 100% of the ref value. The y axis of the graph may represent registration errors and may be expressed as 3σ (3 sigma) in unit of nanometers (nm). Each line in the graph may be a different set of data under the same focus condition.

Referring to the graph of FIG. 6, it may be confirmed that registration error differences are made according to dose differences under the same focus condition. That is, a dose may influence registration, as well as a pattern size. For example, in a focus condition F0, a dose of a ref value may have a registration error of about 1.2 nm, whereas a dose of 20% may have a registration error of about 1.4 nm and a dose of −20% may have a registration error of about 1.6 nm. The dose of 20% and the dose of −20% may increase registration errors of about 0.2 nm and about 0.4 nm, respectively, compared to the dose of the ref value.

As described above, an E-beam exposure apparatus may use a multi-beam in an E-beam exposure process, and the E-beam exposure apparatus is also called a Multi-Beam Mask Writer (MBMW). The MBMW performs exposure using a bundle of beams, and the MBMW may have difficulty in individually responding to focus changes of individual beams. The MBMW may respond to focus changes of beams by performing exposure based on an isofocal-dose with a small (e.g., a smallest) CD change according to a focus change.

In addition, in a mask manufacturing process, high doses may be used to improve pattern quality, and various doses exceeding the isofocal-dose may be used in the process as needed. Also, a method of applying different doses to different positions, even within a same layout to improve pattern quality may be used. As described above with reference to FIG. 6, registration error differences may be made according to dose differences.

According to an embodiment, a method of correcting a registration error of a mask may correct a registration error according to doses by extracting registration error data according to a dose difference of E-beams in a preset process condition through a test and generating a correction map based on the registration error data. By compensating for a dose causing a registration error, the registration error may be corrected. In a situation in which processes using various doses increase, the registration error difference according to doses may be corrected, a mask with improved registration characteristics may be manufactured, and overlay quality of a wafer upon manufacturing of an integrated circuit using the mask may be improved.

Before an operation of correcting a registration error according to a process condition, an operation of correcting a registration error in view of hardware may be performed. For example, before an operation of extracting registration error data according to a dose difference, an operation of correcting a registration error caused by unique characteristics of the E-beam exposure apparatus may be performed. The registration error caused by the unique characteristics of the E-beam exposure apparatus may be caused, for example, by bending of a position detection mirror of the substrate stage 182 (see FIG. 1). By performing correction in view of hardware before correcting a registration error caused by a dose that is a process condition, it may be confirmed that a registration error according to a result of the above-described test has been caused by a dose difference.

Referring again to FIG. 4, a method of correcting a registration error of a mask, according to an embodiment, may include operation S13 of dividing the pattern area 40 (see FIG. 2) of the mask into a preset unit area and generating a dose map. Operation S13 of generating the dose map may be performed by the correction map generator 260 (see FIG. 3). The preset unit area of the dose map may be defined according to a designer's need and may be the pixel 33 (see FIG. 2), the irradiation area 44, which may be irradiated with one multi-beam shot, or the stripe area 42. The dose map gives an incident irradiation amount for each pixel 33. The incident irradiation amount for each pixel 33 may be an incident irradiation amount that is expected to be irradiated to the corresponding pixel 33.

Operation S14 of generating a correction map based on the registration error data according to the dose difference and the dose map may be performed. The correction map may be generated by the correction map generator 260 (see FIG. 3) of the control circuit 200. The correction map may include a correction value for correcting a registration error. Again, the registration error may be the positional error of the mask pattern.

According to an embodiment, the correction map may be generated to correspond to each exposure unit. A correction map may be generated to correspond to each preset unit area, e.g., the irradiation area 44 (see FIG. 4) of a plurality of preset unit areas over an area of a pattern for a mask MS. A plurality of correction maps, each having a relatively small range, may be merged to form a global map for the area of a pattern for a mask MS.

According to an embodiment, both the first dose having the first error value and the second dose having the second error value may be doses irradiated by an exposure unit. According to an embodiment, the exposure unit may be a unit of the irradiation area 44 that may be irradiated with a multi-beam shot. According to an embodiment, the exposure unit may have a width that is in a range of several micrometers (μm), tens of/m, or hundreds of μm. For example, the exposure unit may have a horizontal width and a vertical width of about 100 μm or less, or may have a horizontal width and a vertical width of about 81 μm. According to an embodiment, the exposure unit may be an image field in an exposure process.

FIG. 7 is a conceptual view illustrating a correction map according to an embodiment.

Referring to FIG. 7, a correction map 10 may be generated by using the registration error data 6, the dose map 7, and a surface roughness map 8. The registration error data 6 may be obtained in operation S12 of extracting the registration error data according to the dose difference of E-beams, as illustrated in FIG. 4, and the dose map 7 may be obtained in operation S13 of dividing the pattern area 40 (see FIG. 2) of the mask into the preset unit area and generating the dose map 7. In addition, the surface roughness map 8 may map how light may be reflected by a surface. The surface roughness map 8 may be a map that represents surface roughness of a blank mask not subjected to exposure.

According to an embodiment, a plurality of correction maps 10 each having a relatively small range may be merged to form a global map 20. The global map 20 may correspond to a front surface of the mask. According to an embodiment, the correction map 10 may be formed for each exposure unit. That is, a plurality of correction maps 10 for local areas may be merged to form the global map 20, and the registration error may be corrected based on the global map 20. According to an embodiment, the registration error may be corrected by correcting positional data of the mask pattern or adjusting the deflection elements of the E-beam exposure apparatus.

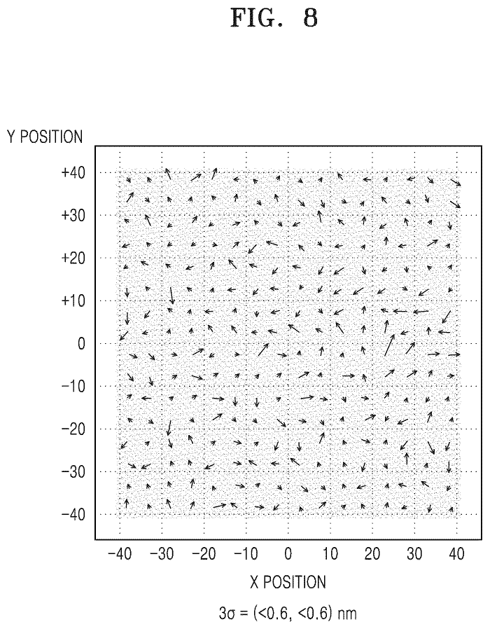

FIG. 8 is a two-dimensional map showing measured results of registration errors of a mask corrected by a registration error correction method according to an embodiment.

A distribution of the registration errors of the mask may be expressed as a two-dimensional map including indicators of direction and magnitude. The distribution of the registration errors of the mask may be expressed as a two-dimensional map including a plurality of arrows, as illustrated in FIG. 8. Directions of the arrows in the two-dimensional map may represent directions of patterns elements shifted from nominal positions (X:0.00, Y:0.00), and lengths of the arrows may represent shift amounts. The two-dimensional map of the registration errors illustrated in FIG. 8 shows a result in which a maximum 30 in the x direction is about 0.6 nm and a maximum 30 in the y direction is 0.6 about nm.

A mask manufacturing method according to an embodiment may include operation S10 (see FIG. 4) of correcting a registration error, including a method of correcting a registration error of a mask, as described above with reference to FIGS. 1 to 7, and operation S20 (see FIG. 4) of exposing the mask by reflecting a correction map.

In a mask manufacturing method according to an embodiment, the mask may be a transmissive mask or a reflective mask. In the case of a transmissive mask, exposure light may pass through the transmissive mask and be projected onto a wafer that is a target to be exposed. In the case of a reflective mask, exposure light may be reflected from the reflective mask and be projected onto a wafer that is a target to be exposed.

The transmissive mask may include a photomask. The photomask may have a structure in which a light shield layer is positioned on a transparent substrate. The light shield layer may be an opaque layer disposed on the transparent substrate. The transparent substrate may include a Low Thermal Expansion Material (LTEM). In other words, the transparent substrate may include a material having a small Coefficient of Thermal Expansion (CTE). For example, the transparent substrate may include, for example, glass, silicon (Si), or quartz. Moreover, the light shield layer may include chrome. However, a material of the light shield layer is not limited to chrome.

A series of processes including an E-beam exposure process, a developing process, and an etching process, as described herein, may be performed on a blank photomask to form a pattern in the light shield layer. As a result of forming the pattern in the light shield layer, exposure light may be transmitted through an open area of the pattern and projected onto a wafer that is a target to be exposed (see FIG. 1). Accordingly, a pattern transferred to the wafer may correspond to the shape of the open area of the pattern of the light shield layer. The pattern may be reversed and transferred according to characteristics of a photoresist on the wafer. For example, the pattern may be reversed by the electromagnetic-optical projector elements.

The reflective mask may include, for example, an extreme ultraviolet (EUV) mask. The EUV mask is described in detail with reference to FIG. 9.

FIG. 9 is an cross-sectional view of a mask MS formed by a mask manufacturing method according to an embodiment. The mask MS may be an EUV mask.

A EUV mask may include a substrate 310, a reflective multilayer 320, a capping layer 330, and an absorptive layer 340. The substrate 310 may include an LTEM, that is, a material having a small CTE. For example, the substrate 310 may include, for example, glass, silicon, or quartz.

The reflective multilayer 320 may be disposed on the substrate 310. The reflective multilayer 320 may reflect light (for example, EUV rays) that has entered the reflective multilayer 320. The reflective multilayer 320 may include a Bragg reflector. The reflective multilayer 320 may have a multilayer structure in which two material layers are alternately stacked in tens of layers. More specifically, in the reflective multilayer 320, a first material layer 321 having a low refractive index and a second material layer 322 having a high refractive index may be stacked in about 40 to 60 layers. Herein, the first material layer 321 may include molybdenum (Mo) and the second material layer 322 may include silicon (Si). Materials of the first material layer 321 and the second material layer 322 are not limited, and other materials may be used.

The capping layer 330 may be positioned on the reflective multilayer 320. The capping layer 330 may reduce or prevent damage to the reflective multilayer 320 and surface oxidation of the reflective multilayer 320. The capping layer 330 may include, for example, ruthenium (Ru). A material of the capping layer 330 is not limited to ruthenium (Ru). In addition, the capping layer 330 may be optional. Accordingly, in some embodiments, the capping layer 330 may be omitted.

The absorptive layer 340 may be disposed on the capping layer 330. In a case in which the capping layer 330 is omitted, the absorptive layer 340 may be disposed on the reflective multilayer 320, for example, the second material layer 322. The absorptive layer 340 may include a material that absorbs incident light. The absorptive layer 340 may absorb incident light, for example, an EUV ray. An EUV ray that is incident to the absorptive layer 340 may be absorbed and may fail to arrive at the reflective multilayer 320. The absorptive layer 340 may include, for example, tantalum nitride (TaN), tantalum hafnium (TaHf), tantalum hafnium nitride (TaHfN), tantalum boron silicon (TaBSi), tantalum boron silicon nitride (TaBSiN), tantalum boron nitride (TaBN), tantalum silicon (TaSi), silicon tantalum nitride (TaSiN), germanium tantalum (TaGe), germanium tantalum nitride (TaGeN), tantalum zirconium (TaZr), or tantalum zirconium nitride (TaZrN), or a combination thereof. A material of the absorptive layer 340 is not limited, and other materials may be used.

A series of processes including an E-beam exposure process, a developing process, and an etching process, as described herein, may be performed on a blank EUV mask to form a pattern in the absorptive layer 340. The pattern in the absorptive layer 340 may include an open area. The open area may expose the reflective multilayer 320. An EUV ray L may arrive at the reflective multilayer 320 through the open area of the pattern, be reflected from the reflective multilayer 320, and projected onto a wafer that is a target to be exposed. Accordingly, a pattern transferred on the wafer may correspond to the shape of the open area of the pattern of the absorptive layer 340.

After a blank mask is prepared, an E-beam resist layer may be applied on the blank mask. More specifically, in a case in which the blank mask is a photomask (e.g., mask MS, FIG. 1), an E-beam resist layer may be applied on the light shield layer. Also, in a case in which the blank mask is an EUV mask, an E-beam resist layer may be applied on the absorptive layer.

Operation S20 of exposing the mask by reflecting the correction map may be performed by applying the E-beam resist layer and then performing an E-beam exposure process on the E-beam resist layer. After the E-beam exposure process is performed, the E-beam resist layer may be developed to form an E-beam resist pattern. An operation of forming the E-beam resist pattern may further include a process of developing the E-beam resist layer, a cleaning process, and a bake process.

After the E-beam resist pattern is formed, a lower layer may be etched by using the E-beam resist pattern as an etching mask and form a pattern. More specifically, in the case of the photomask, the light shield layer may be etched by using the E-beam resist pattern as an etching mask to form a pattern in the light shield layer. In the case of the EUV mask, the absorptive layer may be etched by using the E-beam resist pattern as an etching mask to form a pattern in the absorptive layer.

After the pattern is formed, a series of processes may be performed to complete a mask MS. The series of processes may include, for example, a development process, an etching process, and a cleaning process. Also, the series of processes may include a measurement process, a defect detection process, or a defect repair process. Furthermore, the series of processes may include a pellicle application process. Herein, the pellicle application process may be a process of attaching a pellicle to a surface of a mask after it is confirmed that neither contamination particles nor chemical stains exist through final cleaning and inspection. A pellicle disposed on a surface of a mask may protect the mask against subsequent contamination during delivery of the mask and during the available life of the mask. For example, the pellicle may have high mechanical toughness, high transparency to an E-beam, thermal stability, and chemical stability.

According to an embodiment, while a mask is manufactured, Contrast Enhancement by Dose (CED) modulation may be performed. The CED modulation may be a task of selecting or optimizing a dose for each position of a pattern to enhance a dose margin. Here, optimization includes selecting an optimized dose for each position of a pattern that improves a dose margin. The CED modulation may increase or decrease a dose for each position of a pattern to enhance a dose margin of the pattern. According to an embodiment, the CED modulation may be performed in the operation of generating a dose map. Data about an optimized dose, that is, an improved dose, may be transferred from the control circuit 200 (see FIG. 3) of the E-beam exposure apparatus 1000 (see FIG. 3) to the exposure mechanism 100 (see FIG. 1), and writing may be performed based on the data about an optimized dose.

As examples of methods of applying the CED modulation, CED modulation may increase a dose for the center of a pattern or increase a dose for the entirety of the pattern may be applied to a pattern having a size that is smaller than a preset size, and CED modulation may increase a dose for an edge area of a pattern may be applied to a pattern of the preset size or more.

According to an embodiment, after the CED modulation is performed, registration error data (that is, registration error data according to a process condition) may be extracted in a dose condition in which a dose has increased or decreased, and a correction map may be generated by reflecting the registration error data.

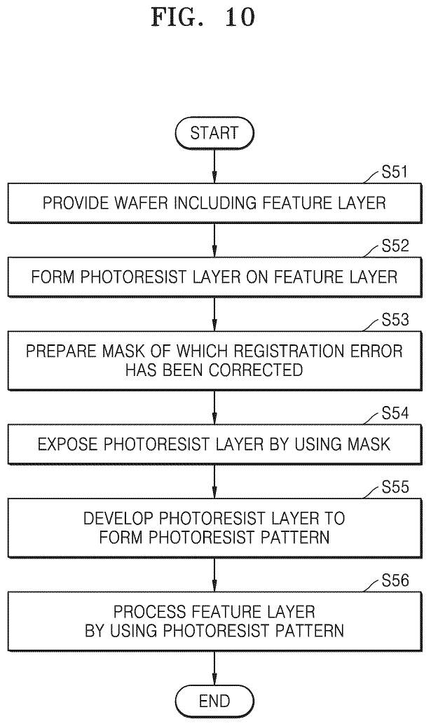

FIG. 10 is a flowchart illustrating an integrated circuit manufacturing method according to an embodiment.

Referring to FIG. 10, an integrated circuit manufacturing method according to an embodiment may include operation S51 of providing a wafer including a feature layer, operation S52 of forming a photoresist layer on the feature layer, operation S53 of preparing a mask of which a registration error has been corrected, operation S54 of exposing the photoresist layer by using the mask, operation S55 of developing the photoresist layer to form a photoresist pattern, and operation S56 of processing the feature layer by using the photoresist pattern. Hereinafter, an integrated circuit manufacturing method according to an embodiment is described in detail.

A wafer including a feature layer may be provided. The feature layer may be a conductive layer or an insulating layer formed on the wafer. For example, the feature layer may be formed of metal, a semiconductor, or an insulating material. In some embodiments, the feature layer may be a part of the wafer.

A photoresist layer may be formed on the feature layer. The photoresist layer may be formed of an EUV resist material, although not limited thereto. For example, the photoresist layer may be formed of a resist for F₂ excimer laser (157 nm), a resist for ArF excimer laser (193 nm), or a resist for KrF excimer laser (248 nm). The photoresist layer may be formed of a positive-type photoresist or a negative-type photoresist.

In some embodiments, to form the photoresist layer formed of the positive-type photoresist, a photoresist composition including a photosensitive polymer having an acid-labile group, a potential acid, and a solvent may be spin-coated on the feature layer.

In some embodiments, the photosensitive polymer may include a (meth) acrylate based polymer. The (meth) acrylate based polymer may be an aliphatic (meth) acrylate-based polymer. For example, the photosensitive polymer may be polymethylmethacrylate (PMMA), poly(t-butylmethacrylate), poly(methacrylic acid), poly(norbornylmethacrylate), or a binary copolymer or terpolymer of repeating units of (meth) acrylate-based polymers, or a mixture thereof. The photosensitive polymers may be substituted with various acid-labile protecting groups. The protecting groups may include a tertbutoxycarbonyl (t-BOC), tetrahydropyranyl (TC), trimethylsilyl, phenoxyethyl, cyclohexenyl, tert-butoxycarbonylmethyl, tert-butyl, adamantyl, or norbornyl group. The inventive concept is not limited to the examples, and other materials may be used.

In some embodiments, the potential acid may include photoacid generator (PAG), thermoacid generator (TAG), or a combination thereof. In some embodiments, the PAG may include a material that generates an acid upon exposure to any ray selected from among an EUV ray (1 nm to 31 nm), an F₂ excimer laser (158 nm), an ArF excimer laser (193 nm), or a KrF excimer laser (248 nm). The PAG may include, for example, onium salts, halogen compounds, nitrobenzyl esters, alkylsulfonates, diazonaphthoquinones, iminosulfonates, disulfones, diazomethanes, or sulfonyloxyketones.

A mask for which a registration error has been corrected may be prepared. Operation S53 of preparing a mask for which a registration error has been corrected may include a method S10 of correcting a registration error of a mask, as illustrated in FIG. 2.

The photoresist layer may be exposed by using a photomask for which a registration error has been corrected. In some embodiments, in the exposure process, the photoresist layer may be exposed with an EUV ray reflected from the photomask.

The exposed photoresist layer may be developed to form a photoresist pattern.

The feature layer may be processed by using the photoresist pattern. In some embodiments, to process the feature layer, the feature layer may be etched by using the photoresist pattern as an etching mask to form a feature pattern. In some embodiments, to process the feature layer, impurity ions may be implanted into the feature layer by using the photoresist pattern as an ion implantation mask. In some embodiments, to process the feature layer, a process film may be formed on the feature layer exposed through the photoresist pattern formed in operation S55. The process film may include a conductive layer, an insulating layer, or a semiconductor layer, or a combination thereof.

Herein, the inventive concept has been described with reference to embodiments shown in the drawings. However, embodiments are only examples, and it will be understood by those skilled in that art that various modifications and other equivalent embodiments may be made from the present disclosure. Accordingly, the scope of the inventive concept should be determined according to the technical concept of the attached claims.

While the inventive concept has been particularly shown and described with reference to embodiments thereof, it will be understood that various changes in form and details may be made therein without departing from the spirit and scope of the following claims.

What is claimed is:

1. A method of correcting a registration error of a mask manufactured using an exposure apparatus, comprising:
performing a test exposure using the exposure apparatus;
extracting registration error data according to a dose difference of beams in a preset process condition, through the test exposure;
providing a dose map for a pattern area of the mask; and
generating a correction map using the dose map and the registration error data.

2. The method of claim 1, wherein the registration error data includes a first error value caused by a first dose and a second error value caused by a second dose that is different from the first dose, in a same focus condition of the beams, wherein the beams are E-beams.

3. The method of claim 2, wherein the first dose is selected to reduce a Critical Dimension (CD) change of a pattern according to a focus change of the exposure apparatus.

4. The method of claim 2, wherein the correction map is configured to correct a registration error caused upon exposure of the mask with the second dose by comparing the first error value with the second error value.

5. The method of claim 1, further comprising:
generating a plurality of correction maps, including the correction map, each of the correction maps corresponding to an exposure unit, and the plurality of correction maps corresponding to the pattern area of the mask; and
generating a global map corresponding to the pattern area of the mask by merging the plurality of correction maps.

6. The method of claim 5, wherein the exposure unit is an irradiation area of the exposure apparatus that is exposed in a multi-beam shot, and a horizontal width and a vertical width of the exposure unit are each about 100 micrometers or less.

7. The method of claim 1, further comprising correcting a registration error caused by a characteristic of the exposure apparatus before the registration error data is extracted according to the dose difference of the beams.

8. The method of claim 1, wherein the mask includes a substrate, a reflective multilayer applied stacked on the substrate, a capping layer, and an absorptive layer.

9. The method of claim 1, wherein generating the correction map further uses a surface roughness map of the mask representing a surface roughness of the mask before exposure.

10. A method of manufacturing a mask, the method comprising:
performing a test exposure;
extracting registration error data according to a dose difference of beams in a preset process condition, through the test exposure;
providing a dose map for a pattern area of the mask divided into preset unit areas;
generating a correction map using the dose map and the registration error data; and
exposing the mask by using the correction map.

11. The method of claim 10, wherein the registration error data includes a first error value caused by a first dose and a second error value caused by a second dose that is different from the first dose, in a same focus condition of the beams, wherein the beams are E-beams, and the method further comprises correcting a registration error generated upon exposure with the second dose by comparing the second error value with the first error value.

12. The method of claim 11, wherein the second dose is in a range of about 120% to about 200% of the first dose.

13. The method of claim 10, wherein the correction map is generated to correspond to each preset unit area of the preset unit areas, the method further comprising:
generating a global map corresponding to a front surface of the mask by merging the correction maps for the preset unit areas,
wherein the mask is exposed by using the global map.

14. The method of claim 10, wherein the generating of the dose map includes Contrast Enhancement by Dose (CED) modulation.

15. The method of claim 10, wherein the mask is a mask for extreme ultraviolet (EUV) lithography.

16. A method of manufacturing an integrated circuit, the method comprising:
providing a wafer including a feature layer;
forming a photoresist layer on the feature layer;
preparing a mask for which a registration error has been corrected;
exposing the photoresist layer using the mask;
developing the photoresist layer to form a photoresist pattern; and
processing the feature layer using the photoresist pattern,
wherein the preparing of the mask for which the registration error has been corrected comprises:
performing a test exposure using an E-beam exposure apparatus;
extracting registration error data according to a dose difference of E-beams in a preset process condition, through the test exposure;
providing a dose map for a pattern area of the mask divided into preset unit areas;
generating a correction map using the registration error data and the dose map; and
exposing the mask using the correction map correcting the registration error of the E-beam exposure apparatus.

17. The method of claim 16, wherein the registration error data includes a first error value caused by a first dose and a second error value caused by a second dose in a same focus condition of the E-beams.

18. The method of claim 17, wherein the correction map is generated to correspond to an exposure unit of which a horizontal width and a vertical width are about 100 micrometers or less, and
the registration error data includes error data caused by a first dose irradiated within the exposure unit and a second dose that is different from the first dose.

19. The method of claim 17, wherein the first dose is selected to reduce a Critical Dimension (CD) change of a pattern according to a focus change of the E-beams.

20. The method of claim 16, wherein the processing of the feature layer comprises forming a feature pattern by etching the feature layer using the photoresist pattern as an etching mask.
